(19) United States
(12) Patent Application Publication
(10) Pub. No.: US 2013/0127538 A1
(43) Pub. Date: May 23, 2013

(54) CMOS INTEGRATED CIRCUIT AND AMPLIFYING CIRCUIT

(71) Applicant: Tadamasa MURAKAMI, Yokohama (JP)

(72) Inventor: Tadamasa MURAKAMI, Yokohama (JP)

(21) Appl. No.: 13/612,118

(22) Filed: Sep. 12, 2012

(30) Foreign Application Priority Data
Nov. 21, 2011 (JP) 2011-254071

(51) Int. Cl. H03F 3/16; H01L 27/092

(52) U.S. Cl. 330/277; 257/351; 257/E27.062

(57) ABSTRACT

There is provided a CMOS integrated circuit suppressing gate resistance and preventing increase in noise figure (NF), while an input transistor has a comb structure. The transistor includes: a gate electrode extended from a gate wiring to form a comb shape and receiving an input signal from an input terminal; a source electrode extended from a source wiring facing the gate wiring to form a comb shape and connected to a ground terminal, comb teeth thereof being interposed in every other space between comb teeth of the gate electrode; a drain electrode extended from a drain wiring facing the gate wiring to form a comb shape, comb teeth thereof being interposed in every other space between comb teeth of the gate electrode where the comb teeth of the source electrode are absent, wherein an overlapping region between the gate electrode and the source electrode or the drain electrode is absent.

### CROSS-REFERENCE TO RELATED APPLICATIONS

This application claims the priority of Japanese Patent Application No. 2011-254071 filed on Nov. 21, 2011, in the Korean Intellectual Property Office, the disclosure of which is incorporated herein by reference.

### BACKGROUND OF THE INVENTION

1. Field of the Invention

The present invention relates to a complementary metal-oxide-semiconductor (CMOS) integrated circuit and an amplifying circuit.

2. Description of the Related Art

In a wireless communications system such as a mobile phone or a wireless data communications device, an amplifying circuit for amplifying a received signal may be installed on a signal-receiving side. An example of an amplifying circuit is a low noise amplifier (LNA). An LNA amplifies a signal while reducing noise generated in the circuit itself to the lowest possible level thereof, and thus is an essential circuit that is disposed at a front end of a wireless signal receiving circuit.

In the case of implementing an LNA using a complementary metal oxide semiconductor (CMOS), manufacturing costs of the LNA may be reduced. Therefore, demand for this scheme has increased. Further, a reduction in noise figure (NF) is always required due to the original role of the LNA.

In an input transistor of the LNA implemented by CMOS (CMOS LNA), the NF is known to be deteriorated due to resistance generated by wirings in respective portions of the transistor in addition to noise generated in a source, a gate, and a drain, which are original portions of the transistor. One of reasons for NF deterioration is the generation of noise from the resistance of gate wiring. In order to suppress this noise, an input transistor is formed to have a comb-shaped structure, and a gate potential is connected to both ends of a comb tooth, thereby significantly reducing the resistance of the gate wiring.

When an input transistor is formed to have a comb-shaped structure and a gate potential is connected to both ends of a comb tooth thereof, a gate-source capacitance and a gate-drain capacitance are necessarily increased (please see Non-Patent Document 1). Therefore, the increases in gate-source capacitance and gate-drain capacitance may cause an increase in the NF, resulting in deterioration in the performance of the CMOS LNA.

### RELATED ART DOCUMENT

(Non-Patent Document 1) The design of CMOS radio-frequency integrated circuits/Thomas H. Lee, Cambridge University Press. Page 287

### SUMMARY OF THE INVENTION

An aspect of the present invention provides a complementary metal-oxide-semiconductor (CMOS) integrated circuit and an amplifying circuit having an improved structure capable of suppressing gate resistance and preventing an increase in a noise figure (NF), while an input transistor has a comb structure.

According to an aspect of the present invention, there is provided a CMOS integrated circuit including a transistor, the transistor including: a gate electrode extended from a gate wiring to form a comb shape and receiving an input signal from a signal input terminal; a source electrode extended from a source wiring facing the gate wiring to form a comb shape and connected to a ground terminal, comb teeth of the source electrode being interposed in every other space between comb teeth of the gate electrode; and a drain electrode extended from a drain wiring facing the gate wiring to forma comb shape, comb teeth of the drain electrode being interposed in every other space between the comb teeth of the gate electrode where the comb teeth of the source electrode are absent, wherein an overlapping region between the gate electrode and the source electrode or the drain electrode is absent.

According to this configuration, the transistor may include the gate electrode extended from the gate wiring to form the comb shape and receiving the input signal from the signal input terminal; the source electrode extended from the source wiring facing the gate wiring to form the comb shape and connected to the ground terminal, the comb teeth of the source electrode being interposed in every other space between the comb teeth of the gate electrode; and the drain electrode extended from the drain wiring facing the gate wiring to form the comb shape, the comb teeth of the drain electrode being interposed in every other space between the comb teeth of the gate electrode where the comb teeth of the source electrode are absent. No overlapping region between the gate electrode and the source electrode or the drain electrode may be present. Thus, while the transistor may have the comb structure, gate resistance may be suppressed and an increase in the NF may be prevented.

Distances between the gate wiring and the source electrode and between the gate wiring and the drain electrode may be set to allow a noise figure of the transistor to have a predetermined value or less.

Distances between the gate wiring and the source electrode and between the gate wiring and the drain electrode may be larger than a minimum distance determined by a process rule.

A distance between the comb teeth of the source electrode and a distance between the comb teeth of the drain electrode may be larger than a minimum distance determined by the process rule.

The CMOS integrated circuit may be formed on a silicon on insulator (SOI) substrate.

According to another aspect of the present invention, there is provided an amplifying circuit including the CMOS integrated circuit as described above.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a diagram showing an examplary configuration of a wireless communications device according to an embodiment of the present invention;

FIG. 2 is a diagram showing an examplary configuration of an LNA;

FIG. 3 is a view showing an example of a layout arrangement of a MOSFET according to the related art;

FIG. 4 is a diagram showing a gate-source capacitance, a gate-drain capacitance, and a source-drain capacitance in the MOSFET;

FIG. 5 is a view showing an example of a layout arrangement of a MOSFET included in the LNA according to the embodiment of the present invention;

FIG. 6 is a graph showing a comparison between NF of an LNA according to the related art and NF of the LNA according to the embodiment of the present invention; and

FIG. 7 is a view showing another layout arrangement example of the MOSFET included in the LNA according to the embodiment of the present invention.

### DETAILED DESCRIPTION OF THE EMBODIMENTS

Hereinafter, embodiments of the present invention will be described in detail with reference to the accompanying drawings. In addition, throughout the present specification and the accompanying drawings, components having the same function will be denoted by the same reference numerals and an overlapped description will be omitted.

### 1. Embodiment of the Present Invention

Examplary Configuration of Wireless Communications Device]

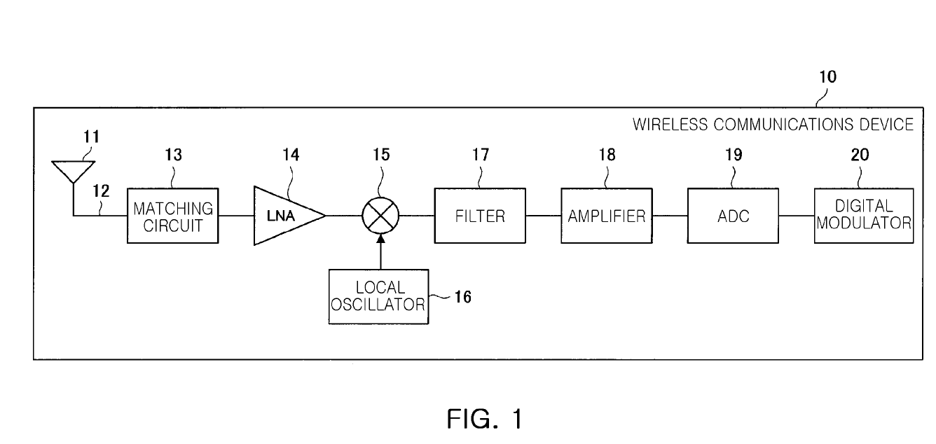

First, an examplary configuration of a wireless communications device according to an embodiment of the present invention will be described. FIG. 1 is a diagram showing an examplary configuration of a wireless communications device according to an embodiment of the present invention. Hereinafter, the exemplary configuration of a wireless communications device according to an embodiment of the present invention will be described with reference to FIG. 1.

As shown in FIG. 1, a wireless communications device 10 according to an embodiment of the present invention may include an antenna 11, a transmission path 12, an impedance matching circuit 13, a low noise amplifier (LNA) 14, a mixer 15, a local oscillator 16, a filter 17, an amplifier 18, an analog-to-digital converter (ADC) 19, and a digital modulator 20.

The antenna 11 transmits and receives radio waves. In the present embodiment, the wireless communications device 10 transmits and receives a GHz-band high frequency signal, particularly a 5 GHZ-band high frequency signal. The high frequency signal received by the antenna 11 is transmitted to the impedance matching circuit 13 through the transmission path 12.

The impedance matching circuit 13 performs impedance matching, in which reflection of the high frequency signal into the transmission path 12 is minimized. The high frequency signal received by the antenna 11 is transmitted to the impedance matching circuit 13 via the transmission path 12, and is then transmitted to the LNA 14.

The LNA 14 amplifies the high frequency signal transmitted from the impedance matching circuit 13. As described above, the LNA 14 performs signal amplification while reducing noise generated in the circuit itself to the lowest possible level thereof. The LNA 14 in the present embodiment is implemented by a complementary metal-oxide-semiconductor (CMOS). The high frequency signal amplified by the LNA 14 is transmitted to the mixer 15.

The mixer 15 multiplies the high frequency signal amplified by the LNA 14 and a high frequency signal output from the local oscillator 16 together. By multiplying the high frequency signal amplified by the LNA 14 and the high frequency signal output from the local oscillator 16, a GHZ-band high frequency signal is converted into a MHz-band signal. The mixer 15 outputs the MHz-band signal to the filter 17.

The local oscillator 16 outputs a predetermined frequency-band high frequency signal. The high frequency signal output from the local oscillator 16 is transmitted to the mixer 15. As described above, by multiplying the high frequency signal amplified by the LNA 14 and the high frequency signal output from the local oscillator 16 in the mixer 15, the GHz-band high frequency signal is converted into the MHz-band signal.

The filter 17 only allows a predetermined frequency region in the signal output from the mixer 15 to pass therethrough. The signal passed through the filter 17 is transmitted to the amplifier 18. The amplifier 18 amplifies the signal passed through the filter 17. The signal amplified by the amplifier 18 is transmitted to the ADC 19.

The ADC 19 converts an analog signal transmitted from the amplifier 18 into a digital signal. The digital signal converted by the ADC 19 is transmitted to the digital modulator 20. The digital modulator 20 modulates the digital signal converted by the ADC 19. Since the digital modulator 20 modulates the digital signal, the wireless communications device 10 may confirm contents of the received high frequency signal.

As above, the examplary configuration of a wireless communications device 10 according to the embodiment of the present invention has been described with reference to FIG. 1. Next, an examplary configuration of the LNA 14 included in the wireless communications device 10 according to the embodiment of the present invention will be described.

[Example of LNA]

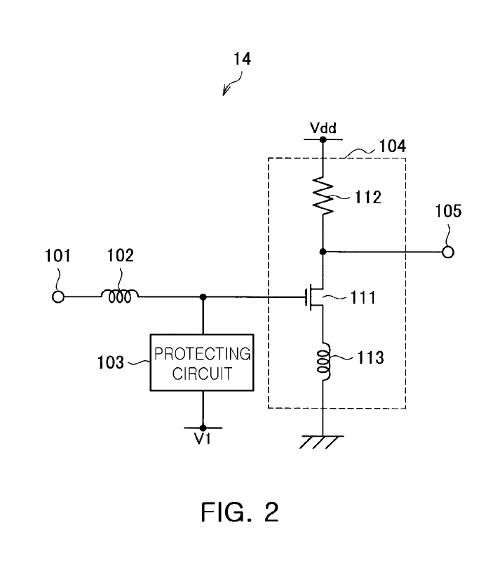

FIG. 2 is a diagram showing an examplary configuration of the LNA included in the wireless communications device according to the embodiment of the present invention. Hereinafter, the examplary configuration of the LNA 14 included in the wireless communications device 10 according to the embodiment of the present invention will be described with reference to FIG. 2.

As shown in FIG. 2, the LNA 14 included in the wireless communications device 10 according to the embodiment of the present invention may include an input terminal 101, an inductor 102, a protecting circuit 103, an amplifying circuit 104, and an output terminal 105. The amplifying circuit 104 may include a MOSFET 111, a load resistor 112, and an inductor 113.

The input terminal 101 is a terminal at which the high frequency signal transmitted by the impedance matching circuit 13 arrives. The input terminal 101 is connected to a gate of the MOSFET 111 included in the amplifying circuit 104 through the inductor 102. The protecting circuit 103 prevents an excessively large signal from being inputted to the amplifying circuit 104. In the case in which a voltage having a predetermined voltage level or higher is generated, the protecting circuit 103 removes components of the voltage, which have a predetermined voltage level or higher, and outputs the resulting signal to the amplifying circuit 104.

The amplifying circuit 104 amplifies the high frequency signal received by the input terminal 101, and then outputs the amplified signal to the output terminal 105. As described above, the amplifying circuit 104 may include the MOSFET 111, the load resistor 112, and the inductor 113. As shown in FIG. 2, in the case of the MOSFET 111, a drain is connected to one end of the load resistor 112, the gate is connected to the input terminal 101, and a source is connected to one end of the inductor 113.

The LNA 14 may be formed on a silicon on insulator (SOI) substrate. The SOI substrate is suitable for an LNA circuit since an inductor or a transistor having a high Q value due to high resistance of the SOI substrate has low parasitic capacitance.

As described above, in the MOSFET 111, an input transistor of the LNA 14 implemented by CMOS, the noise figure (NF) thereof is deteriorated due to resistances generated by wirings in respective portions of the transistor as well as noise generated at the source, the gate, and the drain, which are original portions of the transistor. Accordingly, in the present embodiment, the MOSFET 111 capable of suppressing the increase of NF by improving the layout arrangement thereof will be described.

As above, the configuration of the LNA 14 included in the wireless communications device 10 according to the embodiment of the present invention has been described with reference to FIG. 2. Next, the layout arrangement of the MOSFET 111 included in the LNA 14 according to the embodiment of the present invention will be described.

[Layout Arrangement of MOSFET]

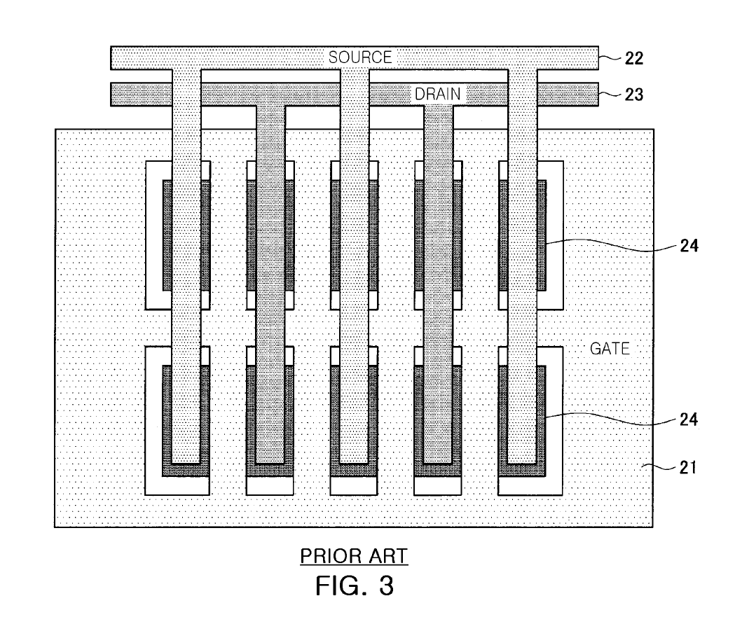

An example of a layout arrangement of a MOSFET according to the related art will be described. FIG. 3 is a view showing an example of a layout arrangement of a MOSFET according to the related art, in particular, a layout arrangement of a MOSFET that promotes the minimization of gate resistance. FIG. 3 shows a gate electrode 21, a source electrode 22, a drain electrode 23, and a well layer 24.

In the related art as shown in FIG. 3, the source electrode 22 and the drain electrode 23 formed above the gate electrode 21 are formed to have a comb-shaped structure, in order to allow for the minimization of MOSFET gate resistance. This MOSFET configuration allows for the minimization of gate resistance.

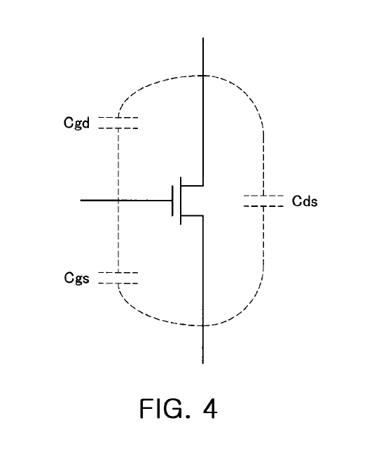

However, when the MOSFET is laid-out as shown in FIG. 3, gate-source capacitance and gate-drain capacitance may be increased. FIG. 4 is a diagram showing a gate-source capacitance, a gate-drain capacitance, and a source-drain capacitance in the MOSFET.

When the MOSFET is laid-out as shown in FIG. 3, capacitances are present in an overlapping region of the gate electrode 21 and the source electrode 22 or the drain electrode 23. That is, the NF may increase due to the presence of capacitances Cgd and Cgs as shown in FIG. 4, and when the MOSFET shown in FIG. 3 is used for a CMOS LAN, the performance of the CMOS LNA may be deteriorated. The deterioration in the performance of the CMOS LNA may prevent improvement in a cut-off frequency, and thus, it is difficult to obtain a gain at a high frequency band.

However, in the present embodiment, the layout arrangement of the MOSFET 111 is improved to thereby suppress the increase of NF. The deterioration in the performance of the LNA 14 may be prevented by suppressing the increase of NF of the MOSFET 111.

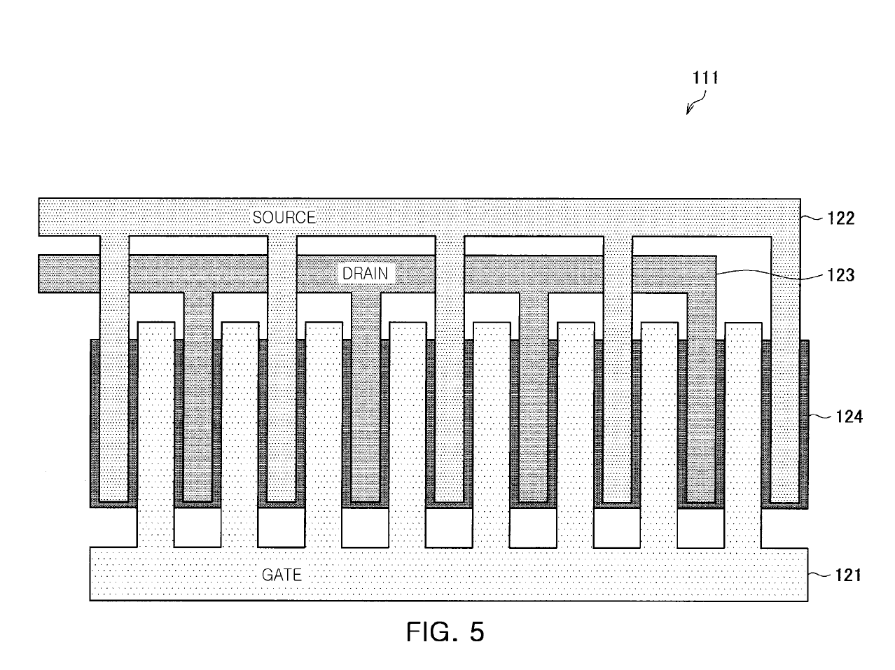

FIG. 5 is a view showing a layout arrangement of a MOSFET included in the LNA according to the embodiment of the present invention. As shown in FIG. 5, the MOSFET 111 included in the LNA 14 according to the embodiment of the present invention may include a gate electrode 121 extended from one main body portion (gate wiring), a source electrode 122 and a drain electrode 123 extended from the other main body portion (source wiring and drain wiring), and a well layer 124.

As shown in FIG. 5, in the MOSFET 111 of the present embodiment, the overlapping region of the gate electrode 121 and the source electrode 122 or the drain electrode 123 is not present. Since the gate electrode 121 does not overlap the source electrode 122 or the drain electrode 123, gate-drain capacitance Cgd and gate-source capacitance Cgs are suppressed at the minimum level, and thus, the cut-off frequency Ft of the LNA 14 may be anticipated to be improved. Since the cut-off frequency Ft of the LNA 14 may be anticipated to be improved, the important factor of the LNA 14, NF, may be anticipated to be improved.

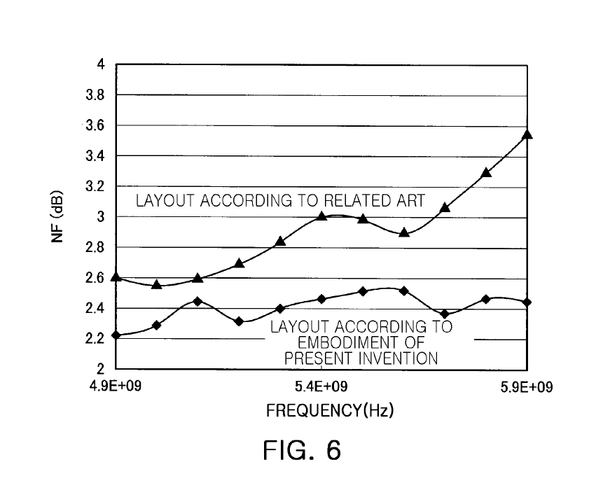

FIG. 6 is a graph showing a comparison between NF of the LNA using the MOSFET of the related art and NF of the LNA using the MOSFET of the present embodiment. On the graph of FIG. 6, frequency is plotted along a horizontal axis and NF is plotted along a vertical axis.

As described above, the wireless communications device 10 of the present embodiment transmits and receives a GHz-band high frequency signal, particularly a 5 GHz-band high frequency signal. In FIG. 6, the graph shows NF values of the LNA when the high frequency signal has a frequency of 4.9 GHz˜5.9 GHz.

It can be seen from FIG. 6, that the NF of the LNA 14 using the MOSFET 111 of the present embodiment was more excellent as compared with the NF of the LNA using the MOSFET of the related art, at any frequency where the high frequency signal had a frequency of 4.9 GHz˜5.9 GHz. Therefore, the MOSFET 111 of the present embodiment is laid out as shown in FIG. 5, and thus, the LNA 14 using the MOSFET 111 of the present embodiment has an improved NF as compared with the LNA using the MOSFET of the related art having the layout shown in FIG. 3.

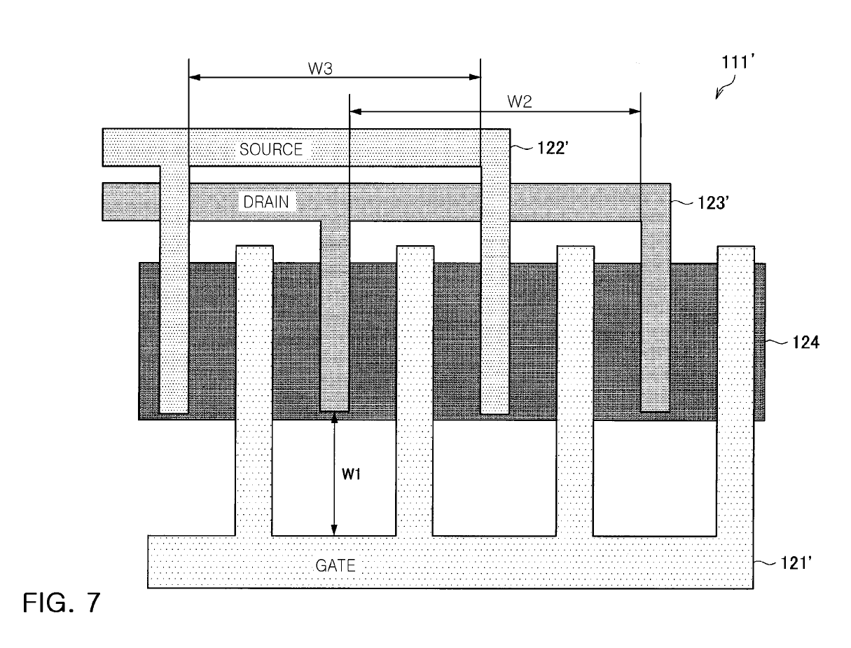

Another layout arrangement example of the MOSFET included in the LNA 14 will be described. FIG. 7 is a view showing another layout arrangement example of the MOSFET included in the LNA according to the present embodiment of the present invention. As shown in FIG. 7, a MOSFET 111′ included in the LNA 14 according to the present embodiment may include a gate electrode 121′ extended from one main body portion (gate wiring), and a source electrode 122′ and a drain electrode 123′ extended from the other main body portion (source wiring and drain wiring).

The MOSFET 111′ shown in FIG. 7 has the same configuration as that shown in FIG. 5, but distances W1 between the gate wiring and the source electrode 122′ and between the gate wiring and the drain electrode 123′, a distance W2 between comb teeth of the drain electrode 123′, and a distance W3 between comb teeth of the source electrode 122′ in the MOSFET 111′ are greater than those of the MOSFET 111 shown in FIG. 5, in order to further reduce gate-drain capacitance Cgd and gate-source capacitance Cgs as compared with the MOSFET 111 shown in FIG. 5.

Conventionally, with respect to the layout around transistors in order to minimize a chip area, the distances W1 between the gate wiring and the source electrode 122′ and between the gate wiring and the drain electrode 123′, the distance W2 between the comb teeth of the drain electrode 123′, and the distance W3 between the comb teeth of the source electrode 122′ are designed with the minimum distance that is determined by a rule of each process technology (a minimum rule). W1 of the MOSFET 111′ shown in FIG. 7 is designed to be greater than a minimum distance thereof determined by the minimum rule. Also, in the same manner, W2 and W3 of the MOSFET 111′ may be designed to be greater than minimum distances thereof determined by the minimum rules, respectively.

In the case of a CMOS process in which a gate length is 0.18 82 m, when a metal 1M is applied to the lowest layer of the source and drain regions and the gate wiring of the MOSFET 111′; the distances W1 between the gate wiring and the source electrode 122′ and between the gate wiring and the drain electrode 123′ are 3 μm; the film thickness of the metal 1M is 0.3 μm; the distance of the metal 1M of the source region and the drain region is 0.2 μm; and the number of comb teeth of the MOSFET 111′ is 100, gate-drain capacitance Cgd and gate-source capacitance Cgs may be about 1 pF.

In the case in which gate-drain capacitance Cgd and gate-source capacitance Cgs of the MOSFET are, for example, 1 pF, this value corresponds to 1/1000 of gate-drain capacitance Cgd and gate-source capacitance Cgs of the MOSFET itself when W1 of the MOSFET 111′ is the above value, and thus, gate-drain capacitance Cgd and gate-source capacitance Cgs can be significantly reduced.

In addition, in the case in which the distance W2 between the comb teeth of the drain electrode 123′or the distance W3 between the comb teeth of the source electrode 122′ is, for example, 1 μm or greater in the CMOS process in which the gate length is 0.18 μm, this may contribute to a reduction in gate-drain capacitance Cgd and gate-source capacitance Cgs.

In the MOSFET 111′ shown in FIG. 7, the overlapping region of the gate electrode 121′ and the source electrode 122′ or the drain electrode 123′ is absent and the distances W1 between the gate wiring and the source electrode 122′ and between the gate wiring and the drain electrode 123′, the distance W2 between the comb teeth of the drain electrode 123′, and the distance W3 between the comb teeth of the source electrode 122′ are greater than those of the MOSFET 111 shown in FIG. 5, so that gate-drain capacitance Cgd and gate-source capacitance Cgs can be reduced to the minimum, to thereby anticipate an improvement in cut-off frequency Ft of the LNA 14. As such, since the cut-off frequency Ft of the LNA 14 can be anticipated to be improved, the important factor of the LNA 14, NF, can be anticipated to be improved.

### 2. Summary

As described above, according to the embodiments of the present invention, the layout of the MOSFET 111 included in the LNA 14 is designed to have no overlapping region of the gate electrode 121 and the source electrode 123 or the drain electrode 123. Since the MOSFET 111 is designed such that the overlapping region of the gate electrode 121 and the source electrode 123 or the drain electrode 123 is not present, gate-drain capacitance Cgd and gate-source capacitance Cgs can be reduced.

As such, gate-drain capacitance Cgd and gate-source capacitance Cgs become smaller, so that the cut-off frequency Ft of the LNA 14 can be improved, and as a result, the important factor of the LNA 14, NF, can be improved.

As set forth above, according to embodiments of the present invention, there is provided a CMOS integrated circuit and an amplifying circuit having an improved structure capable of suppressing gate resistance and preventing an increase in NF, while an input transistor has a comb-shaped structure.

While the present invention has been shown and described in connection with the embodiments, it will be apparent to those skilled in the art that modifications and variations can be made without departing from the spirit and scope of the invention as defined by the appended claims.

1. A complementary metal-oxide-semiconductor (CMOS) integrated circuit comprising a transistor, the transistor including:
a gate electrode extended from a gate wiring to form a comb shape and receiving an input signal from a signal input terminal;
a source electrode extended from a source wiring facing the gate wiring to form a comb shape and connected to a ground terminal, comb teeth of the source electrode being interposed in every other space between comb teeth of the gate electrode; and
a drain electrode extended from a drain wiring facing the gate wiring to form a comb shape, comb teeth of the drain electrode being interposed in every other space between the comb teeth of the gate electrode where the comb teeth of the source electrode are absent,
wherein an overlapping region between the gate electrode and the source electrode or the drain electrode is absent.

2. The CMOS integrated circuit of claim 1, wherein distances between the gate wiring and the source electrode and between the gate wiring and the drain electrode are set to allow a noise figure of the transistor to have a predetermined value or less.

3. The CMOS integrated circuit of claim 1, wherein distances between the gate wiring and the source electrode and between the gate wiring and the drain electrode are larger than a minimum distance determined by a process rule.

4. The CMOS integrated circuit of claim 3, wherein a distance between the comb teeth of the source electrode and a distance between the comb teeth of the drain electrode are larger than a minimum distance determined by the process rule.

5. The CMOS integrated circuit of claim 1, wherein the CMOS integrated circuit is formed on a silicon on insulator (SOI) substrate.

6. An amplifying circuit comprising the CMOS integrated circuit of claim 1.

7. An amplifying circuit comprising the CMOS integrated circuit of claim 2.

8. An amplifying circuit comprising the CMOS integrated circuit of claim 3.

9. An amplifying circuit comprising the CMOS integrated circuit of claim 4.

10. An amplifying circuit comprising the CMOS integrated circuit of claim 5.
